(19) United States
(12) Patent Application Publication
(10) Pub. No.: US 2025/0030223 A1
(43) Pub. Date: Jan. 23, 2025

(54) DYNAMIC POLARIZATION CONTROL FOR OPTICAL EMITTERS

(71) Applicant: Lumentum Operations LLC, San Jose, CA (US)

(72) Inventors: Mahdad MANSOUREE, San Jose, CA (US); Benjamin KESLER, Livemore, CA (US)

(21) Appl. No.: 18/498,760

(22) Filed: Oct. 31, 2023

Related U.S. Application Data
(60) Provisional application No. 63/514,699, filed on Jul. 20, 2023.

(51) Int. Cl. H01S 5/183; H01S 5/042; H01S 5/42

(52) U.S. Cl. CPC H01S 5/18355; H01S 5/04256; H01S 5/423

(57) ABSTRACT

In some implementations, an optical system may include an optical emitter configured to emit a beam, wherein the optical emitter is a vertical cavity surface emitting laser (VCSEL), and wherein the VCSEL is a top-emitting VCSEL or a bottom-emitting VCSEL. The optical system may include a liquid crystal component, the liquid crystal component being disposed on a surface of the optical emitter. The optical system may include a control component.

### CROSS-REFERENCE TO RELATED APPLICATION

This Patent Application claims priority to U.S. Provisional Patent Application No. 63/514,699, filed on Jul. 20, 2023, and entitled “OPTICAL EMITTER WITH LIQUID CRYSTAL LAYER.” The disclosure of the prior Application is considered part of and is incorporated by reference into this Patent Application.

### TECHNICAL FIELD

The present disclosure relates generally to optical emitters and to dynamic polarization control for optical emitters.

### BACKGROUND

Vertical cavity surface emitting lasers (VCSELs) may be used individually and/or in VCSEL arrays for imaging systems, sensing systems, manufacturing systems, or communications systems, among other examples. For example, in a three-dimensional (3D) sensing application, VCSELs provide beams that may be used for facial recognition, gesture recognition, and/or the like. VCSELs may be included in smart phone devices, gaming devices, sensing devices, and/or the like. VCSELs may be used for generating structured light (e.g., in flood illuminators), time of flight (TOF) measurement beams, and/or the like to enable 3D sensing applications, among other examples.

### SUMMARY

In some implementations, an optical system includes an optical emitter configured to emit a beam, wherein the optical emitter is a vertical cavity surface emitting laser (VCSEL), wherein the VCSEL is a top-emitting VCSEL or a bottom-emitting VCSEL; a liquid crystal component, the liquid crystal component disposed on a surface of the optical emitter; and a control component.

In some implementations, a VCSEL assembly includes a VCSEL, wherein the VCSEL includes a substrate, a bottom distributed Bragg reflector (DBR) disposed on the substrate, an active region, and a top DBR, wherein the bottom DBR and the top DBR sandwich the active region; and an integrated liquid crystal cell disposed on the top DBR to control a polarization of light emitted from the VCSEL.

In some implementations, a method includes receiving, by a controller, an input; generating, by the controller, a control signal; and outputting, by the controller, the control signal to a control component of an optical system, the control component being configured to control an orientation of molecules within a liquid crystal component disposed on a surface of an optical emitter of the optical system, a polarization state of light emitted by the optical system being based on the orientation of the molecules within the liquid crystal component.

### BRIEF DESCRIPTION OF THE DRAWINGS

FIGS. 1A and 1B are diagrams depicting a top view of an example emitter and a cross-sectional view of example emitter along the line X-X, respectively.

FIG. 2 is a diagram of an example optical emitter configured for dynamic polarization control.

FIGS. 3-4B are diagrams of example implementations associated with liquid crystal orientation.

FIGS. 5-7 are diagrams of example implementations associated with dynamic polarization control for optical emitters.

FIG. 8 is a flowchart of an example process associated with dynamic polarization control for optical emitters.

### DETAILED DESCRIPTION

The following detailed description of example implementations refers to the accompanying drawings. The same reference numbers in different drawings may identify the same or similar elements.

Optical emitters, such as vertical cavity surface emitting lasers (VCSELs), may emit beams for use in communications systems, measurement systems, sensing systems, manufacturing systems, or imaging systems, among other examples. For example, a VCSEL may emit a beam toward a target and use the beam for three-dimensional (3D) sensing of the target, such as gesture recognition sensing, object recognition sensing, or biometric sensing, among other examples. Some electro-optical systems may emit polarized beams to enable use cases, such as sensing, measurement, communications, manufacturing, or imaging, among other examples. For example, in 3D sensing applications, polarized light may be used to reconstruct a 3D surface in a near field or a far field.

As a result of a circular symmetry in VCSEL design, VCSELs may lack a defined polarization state. Accordingly, to generate a polarized output beam, a polarizing element can be disposed external to a VCSEL and in a field of the VCSEL. In this case, the polarizing element restricts a non-polarized beam, which is directed toward the polarizing element, to a single polarization state of the polarizing element. However, this may result in inefficiency for VCSELs as a result of wasted optical power. In other words, the polarizing element blocks a portion of energy of the beam. To achieve a particular energy level at a target, the VCSEL outputs a beam with a higher energy level that is reduced, when the polarizing element blocks the portion of energy of the beam, down to the particular energy level. Moreover, use of an external polarizing element may result in variations in the output power as the attenuation by the polarizing element may be a function of the polarization state of a beam that is directed to the polarizing element. In other words, a polarization state of a beam emitted by the VCSEL may change over time. As the polarization state of the beam changes, the external polarizer will attenuate the beam by different amounts. Accordingly, an external polarizer may cause variations in the output power of the beam over time, which may negatively affect performance of a system that includes the VCSEL.

Another technique for achieving a single polarization state for a beam is to introduce structural birefringence in a structure of a VCSEL. In this case, introducing structural birefringence disrupts the circular symmetry of the VCSEL, thereby enabling the VCSEL to output polarized light without using a polarizing element that reduces the energy level. However, introducing structural birefringence restricts the VCSEL to outputting light with a single, pre-configured polarization state.

Some implementations described herein enable a VCSEL to dynamically control a polarization state of emitted light. For example, an optical system may include a VCSEL with an integrated liquid crystal (LC) component and a control component, such as a set of control electrodes. The liquid crystal layer generates birefringence, which is dynamically tunable using the control component, with the VCSEL. Based on an alteration to a state of the control component, the control component can cause molecules of the liquid crystal layer to be aligned to a configured orientation, which causes the VCSEL to emit light with a polarization state that is based on the configured orientation. Based on changing a control state of the control component, the orientation of the molecules of the liquid crystal layer and the polarization state of the emitted light are changed. In this way, by providing an integrated liquid crystal component, the optical system enables dynamic polarization control for a VCSEL. Furthermore, by using an integrated liquid crystal component for polarization control, the optical system achieves a higher level of efficiency (e.g., reduced power loss) relative to VCSELs that use external polarizing elements for achieving polarized beams.

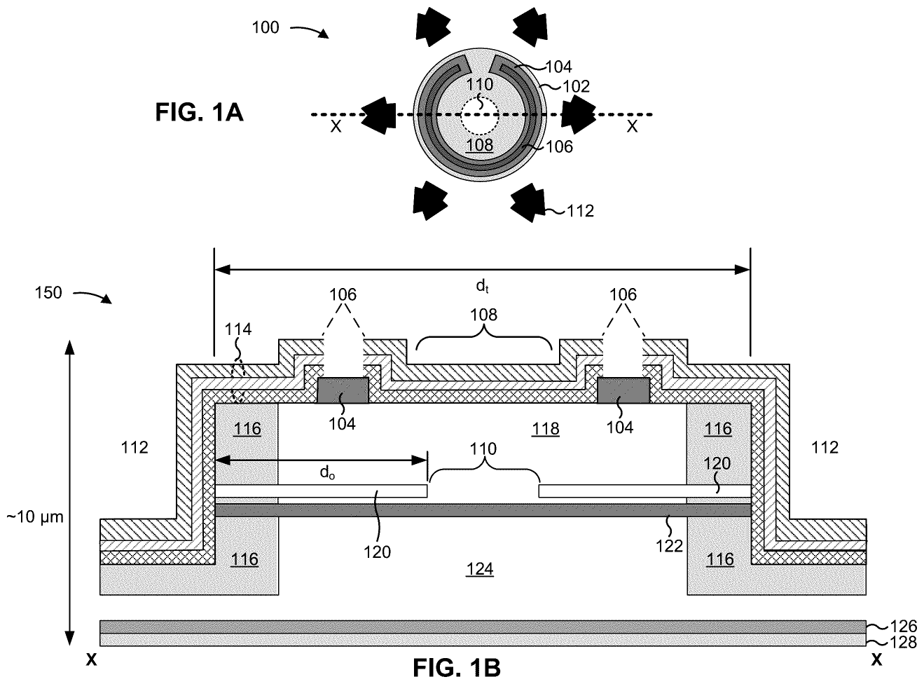

FIGS. 1A and 1B are diagrams depicting a top view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The second area shows an ohmic metal layer 104 covered by a protective layer (e.g., a dielectric layer or a passivation layer) of emitter 100, and the first area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). A first area shows an ohmic metal layer 104 that is exposed by via 106 (e.g., the shape of the first area may be a result of the shape of via 106) while the second area an ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations may be used, such as a compact emitter that includes five trenches 112, seven trenches 112, or another quantity of trenches. In some implementations, trench 112 may encircle emitter 100 to form a mesa structure dₜ. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations may be used. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as dₒ in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

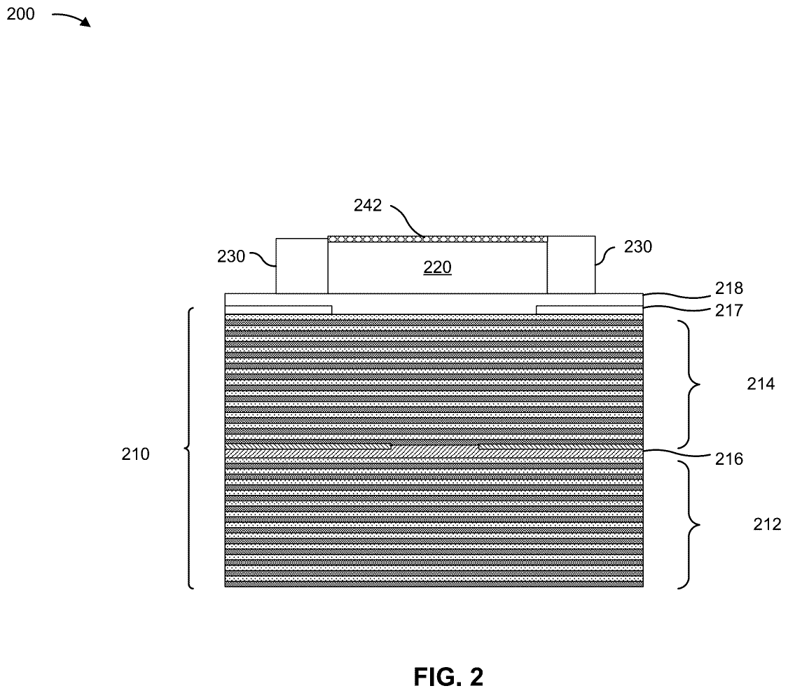

FIG. 2 is a diagram of an example optical system 200 configured for dynamic polarization control. As shown in FIG. 2, optical system 200 includes an optical emitter 210, a liquid crystal component 220, and a control component 230. In some implementations, the optical system 200 may include a VCSEL assembly (e.g., a VCSEL array, a plurality of VCSELs, or a VCSEL and one or more other optical components packaged together or disposed on a common substrate).

In some implementations, the optical emitter 210 may include a VCSEL. For example, the optical emitter 210 may include a top-emitting VCSEL or a bottom-emitting VCSEL. Additionally, or alternatively, the optical emitter 210 may include a VCSEL array. The optical emitter 210 may include a bottom mirror structure 212 and a top mirror structure 214 that sandwich an active region 216, which may include an oxidation aperture. In some implementations, a mirror structure, such as the bottom mirror structure 212 or the top mirror structure 214, may include a set of layers of material. For example, the optical emitter 210 may include alternating high refractive index layers and low refractive index layers of material. The optical emitter 210 may include an emission control component 217. The emission control component 217 may include a set of electrodes on a top surface of the optical emitter 210, as shown, and/or a bottom surface of the optical emitter 210 (not shown) that are configured to control emission of the optical emitter 210. For example, the emission control component 217 may be biased to cause emission, by the optical emitter 210, at a particular wavelength, with a particular intensity, and/or with a particular modulation. In some implementations, the optical emitter 210 may include one or more top surface layers 218, such as a dielectric layer and/or a matching layer. The dielectric layer and/or the matching layer are disposed on the top of the optical emitter 210 to enable the control component 230 and/or the liquid crystal component 220 to be disposed on top of the optical emitter 210.

In some implementations, the optical emitter 210 may include a symmetric VCSEL. For example, the optical emitter 210 may include a VCSEL with circular symmetry, resulting in non-polarized light or variations in the polarization of the light, and may use the liquid crystal component 220 to cause the VCSEL to emit polarized light, as described herein. Additionally, or alternatively, the optical emitter 210 may include a VCSEL with a configured degree of asymmetry that emits a beam with a degree of polarization. In this case, the optical emitter 210 may use the liquid crystal component 220 to enhance the degree of polarization to a configured polarization state. In other words, the liquid crystal component 220 may correct a partial polarization (e.g., more x-polarized light than y-polarized light being emitted) to achieve a complete polarization state (e.g., only x-polarized light being emitted). In some implementations, another optical component may be provided in the optical system 200 to enhance a polarization state (e.g., to cause a polarization state to be closer to a desired polarization state). For example, a polarizing element may be provided. In this case, the presence of the liquid crystal component 220 may reduce an amount of polarization correction that is performed by the polarizing element, thereby reducing an optical power loss relative to a configuration where the polarizing element is the only optical component to cause the emitted beam to be polarized. For example, a polarizing element, alone, may cause a loss of approximately 50% of optical power. In contrast, the liquid crystal component 220 may have an absorption of less than 10%, less than 5%, or less than 1%. Further, when only a small portion of light of a non-desired polarization passes through the liquid crystal component to a polarizing element, the polarizing element causes a loss of approximately 50% on only the small portion of light. Accordingly, providing a liquid crystal component 220 alone (or in combination with a polarizing element) reduces optical power loss associated with emitting a polarized beam.

The liquid crystal component 220 may include a set of liquid crystal molecules that are deposited directly on the optical emitter 210. For example, the liquid crystal component 220 may include a liquid crystal cell containing one or more layers of liquid crystal molecules (e.g., thousands of layers, each having a thickness of approximately 1 nanometer (nm)) orientable by a biasing voltage. In this case, orientation of the liquid crystal molecules alters a refractive index aligned with a liquid crystal optical axis, which results in an alteration of a polarization state of light emitted by the optical emitter 210, as described in more detail herein. The control component 230 may include one or more control elements to control the liquid crystal component 220. For example, the control component 230 may include a set of electrodes to orient liquid crystal molecules in a first orientation corresponding to a first polarization state or in a second orientation corresponding to a second polarization state. Additionally, or alternatively, the control component 230 may include a plurality of sets of electrodes to orient the liquid crystal molecules to a plurality of different orientations corresponding to a plurality of different polarization states.

In some implementations, the control component 230 may include a single pair of electrodes to control a single polarization state (with another, orthogonal polarization state being achieved by a rest-state of the set of liquid crystal molecules, as described herein). Alternatively, the control component 230 may include two pairs or sets of electrodes to control two polarization states (or more by the rest-state of the set of liquid crystal molecules, as described herein). Alternatively, the control component 230 may include three or more pairs or sets of electrodes to control three or more polarization states (e.g., orthogonal polarization states, 45 degree polarization states, or other angles of polarization states). In some implementations, the different polarization states to which the optical emitter 210 can be controlled, in connection with control of the liquid crystal component 220 by the control component 230, may include orthogonal polarization states or non-orthogonal polarization states

In some implementations, the control component 230 may be configured to control the liquid crystal component 220 at a particular switching rate. For example, the control component 230 may switch orientations of liquid crystals within the liquid crystal component 220 a configured quantity of instances within a relatively short interval (e.g., multiple cycles of switching within 1 second). In this way, the control component 230 may enable the optical system 200 to achieve a higher signal-to-noise ratio, obtain sensing information regarding a scene (e.g., by using a plurality of polarization states to capture a plurality of measurements regarding an object), or illuminate different portions of a scene. A scene may include a set of objects or the like that are illuminated by a beam or set of beams from the optical system 200. In some implementations, the control component 230 may be an active or passive controller. For example, the control component 230 may be configured with a set of control states and may statically switch between control states or may be dynamically configured based on feedback from a monitoring component, such as an optical power monitor or other polarization detector.

In some implementations, an anti-reflective (AR) coating 242 is disposed on top of the liquid crystal component 220. For example, one or more layers of an AR material may be disposed on top of the liquid crystal component 220 (e.g., with or without one or more intermediate layers of material) to limit interference feedback to the active region 216. In this way, by providing the AR coating 242, the optical system 200 may achieve a greater level of stability for the active region 216, thereby improving lasing performance. Additionally, or alternatively, the AR coating 242 may mitigate varying reflection as a result of thickness variations across the liquid crystal component 220, which may enable manufacture of the liquid crystal component 220 to increased tolerances, thereby improving manufacturability of the optical system 200. In some implementations, the AR coating 242 may have a refractive index that is matched to the liquid crystal component 220. In some implementations, the AR coating 242 or another coating layer may provide insulation (e.g., thermal or environmental), thereby improving a reliability of the optical system 200.

As indicated above, FIG. 2 is provided as an example. Other examples may differ from what is described with regard to FIG. 2. The number and arrangement of devices shown in FIG. 2 are provided as an example. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) shown in FIG. 2 may perform one or more functions described as being performed by another set of devices shown in FIG. 2.

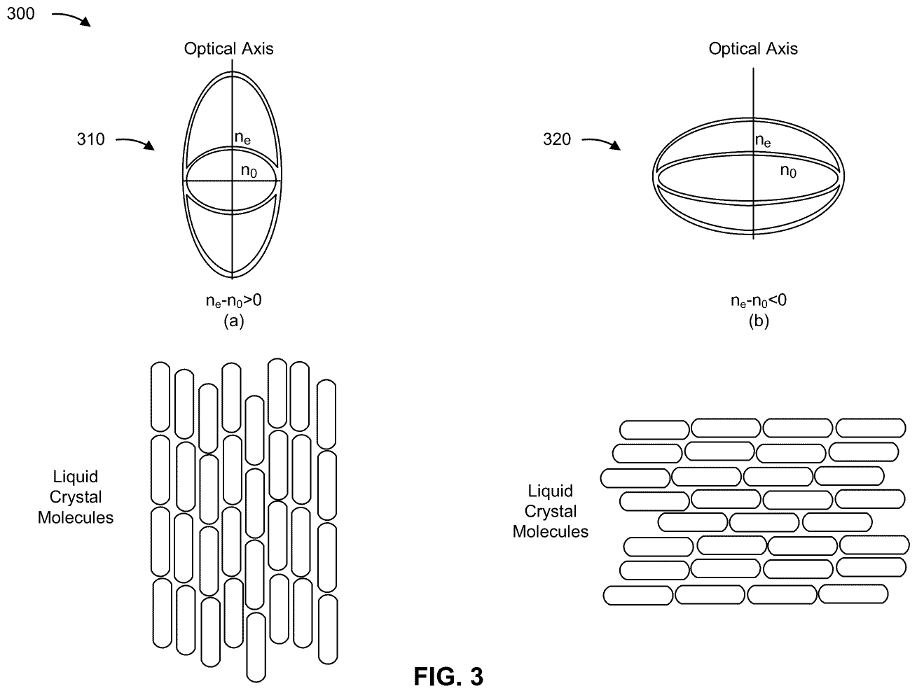

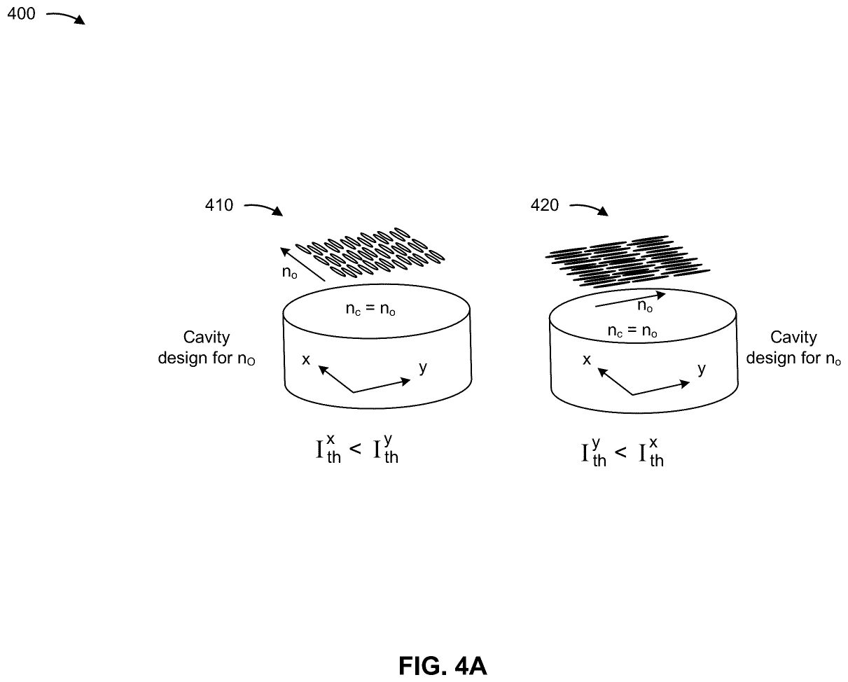

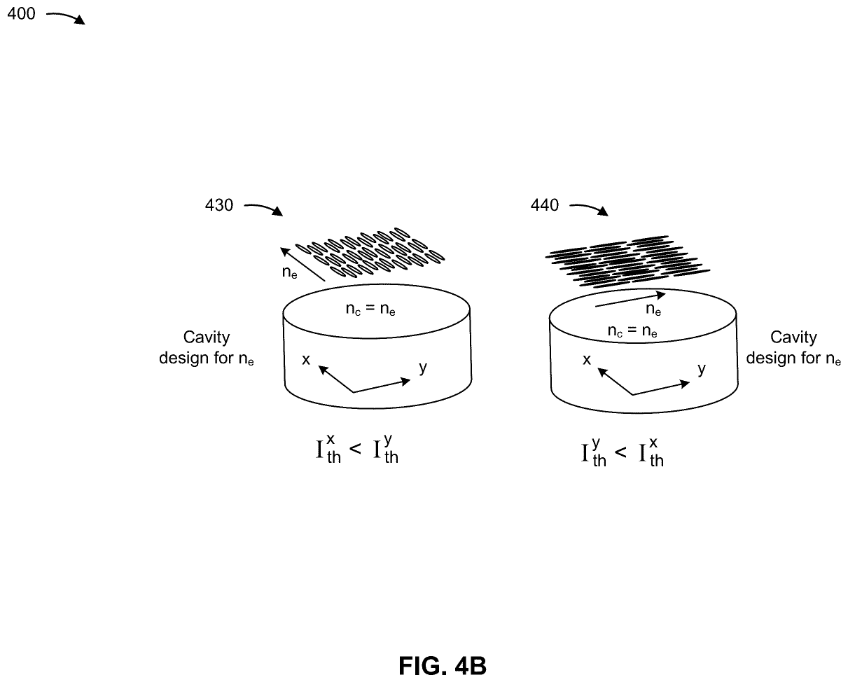

FIG. 3 and FIGS. 4A-4B are diagrams of example implementations 300/400 associated with liquid crystal orientation.

As shown in FIG. 3, a nematic phase liquid crystal may exhibit birefringence. The nematic phase liquid crystal may have one index of refraction (nₑ, the extraordinary refractive index) along the optic axis and another index of refraction (nₒ, the ordinary refractive index) in a direction orthogonal to the optic axis. Liquid crystals may have positive or negative birefringence. For a liquid crystal material with positive birefringence, nₑ>nₒ. For a liquid crystal material with negative birefringence, nₒ>nₑ. As described below, the indices nₒ and nₑ may be associated with the orientation or alignment of the liquid crystal molecules.

The alignment of the liquid crystal molecules may be associated with two polarization states of beams that can be produced by an optical emitter (e.g., the optical emitter 210). For example, a VCSEL cavity may be configured with an effective refractive index n_{c}, such that when n_{c}=nₒ, the VCSEL cavity lases and outputs a polarization that is parallel to the nₒ axis of the liquid crystal. In this case, an ordinary axis of the liquid crystal molecules can be aligned to an x-axis, resulting in x-polarized light, output by the VCSEL, observing the ordinary refractive index nₒ and having in-phase reflection with the VCSEL cavity (e.g., reflection between the top and bottom DBRs of the VCSEL cavity). Similarly, a VCSEL cavity may be configured with an effective refractive index n_{c}, such that when n_{c}=nₑ, the VCSEL cavity lases and outputs a polarization that is parallel to the ne axis of the liquid crystal. In this case, an extraordinary axis of the liquid crystal molecules can be aligned to an y-axis, resulting in y-polarized light, output by the VCSEL, observing the extraordinary refractive index nₑ and having in-phase reflection with the VCSEL cavity (e.g., reflection between the top and bottom DBRs of the VCSEL cavity). Although the x-axis and y-axis are depicted and described herein, it is contemplated that other sets of orthogonal (or non-orthogonal) orientations may be used.

Referring to FIG. 4A, which is an example of a liquid crystal with nₒ aligned to the long axis of the molecule and for the case of n_{c}=nₒ, then the reflection with the VCSEL cavity is in-phase, the VCSEL cavity enhances the x-polarized light resulting in a threshold current for x-polarization, Iₜₕ^{x}, being reduced to a first level that can be satisfied by the x-polarized light. The threshold current Iₜₕ may include a gain threshold for lasing, thereby enabling selection of a desired polarization and filtering of an unwanted polarization, by manipulating an x or y component of the gain threshold, as described herein. For example, reducing the threshold current for x-polarization by having reflection with the VCSEL cavity be in-phase for x-polarized light results in the VCSEL cavity lasing x-polarized light. In contrast, y-polarized light observes a different refractive index that is out-of-phase with the VCSEL cavity, resulting in a threshold current for y-polarization, Iₜₕ^{y}, being increased to a second level that is not satisfied by the y-polarized light (and is greater than Iₜₕ^{x}), as shown in FIG. 4A and by diagram 410.

Accordingly, the VCSEL cavity does not lase y-polarized light. Based on the VCSEL cavity lasing x-polarized light, but not y-polarized light, an optical emitter (which includes the VCSEL cavity) can output a single, polarization of light (e.g., x-polarized light) without optical power being lost by blocking another polarization of light (e.g., the y-polarized light is not lased, rather than being blocked, as described above). In this way, control of the set of liquid crystal molecules induces generation of light with a single, configured polarization and suppresses generation of light with another polarization.

In contrast, when the liquid crystal molecules are rotated, the y-polarized light has in-phase reflection with an ordinary refractive index nₒ being at the top surface of the VCSEL, as shown in FIG. 4A and by diagram 420. In this case, based on the rotation, the VCSEL cavity has a lower threshold current for y-polarization than for x-polarization, resulting in the optical emitter outputting a single polarization of light (e.g., y-polarized light). Although some implementations are described in terms of two orthogonal, mutually exclusive polarizations of light, two or more non-orthogonal polarization states (e.g., polarization states having some x-polarized light and some y-polarized light in different proportions) may be used.

Referring to FIG. 4B, which is an example of a liquid crystal with nₑ aligned to the long axis of the molecule and for the case of n_{c}=nₑ, then the reflection with the VCSEL cavity is in-phase, the VCSEL cavity enhances the x-polarized light resulting in a threshold current for x-polarization, Iₜₕ^{x}, being reduced to a first level that can be satisfied by the x-polarized light. The threshold current Iₜₕ may include a gain threshold for lasing, thereby enabling selection of a desired polarization and filtering of an unwanted polarization, by manipulating an x or y component of the gain threshold, as described herein. For example, reducing the threshold current for x-polarization by having reflection with the VCSEL cavity be in-phase for x-polarized light results in the VCSEL cavity lasing x-polarized light. In contrast, y-polarized light observes a different refractive index that is out-of-phase with the VCSEL cavity, resulting in a threshold current for y-polarization, Iₜₕ^{y}, being increased to a second level that is not satisfied by the y-polarized light (and is greater than Iₜₕ^{x}), as shown in FIG. 4B and by diagram 430.

Accordingly, the VCSEL cavity does not lase y-polarized light. Based on the VCSEL cavity lasing x-polarized light, but not y-polarized light, an optical emitter (which includes the VCSEL cavity) can output a single, polarization of light (e.g., x-polarized light) without optical power being lost by blocking another polarization of light (e.g., the y-polarized light is not lased, rather than being blocked, as described above). In this way, control of the set of liquid crystal molecules induces generation of light with a single, configured polarization and suppresses generation of light with another polarization.

In contrast, when the liquid crystal molecules are rotated, the y-polarized light has in-phase reflection with an ordinary refractive index nₑ being at the top surface of the VCSEL, as shown in FIG. 4B and by diagram 440. In this case, based on the rotation, the VCSEL cavity has a lower threshold current for y-polarization than for x-polarization, resulting in the optical emitter outputting a single polarization of light (e.g., y-polarized light). Although some implementations are described in terms of two orthogonal, mutually exclusive polarizations of light, two or more non-orthogonal polarization states (e.g., polarization states having some x-polarized light and some y-polarized light in different proportions) may be used.

As indicated above, FIGS. 3-4B are provided as examples. Other examples may differ from what is described with regard to FIGS. 3-4B.

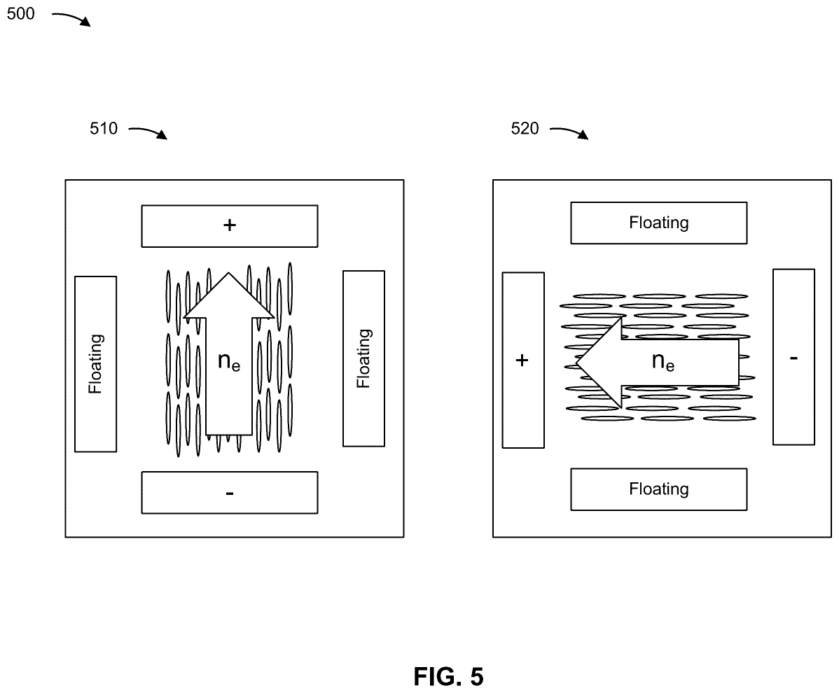

FIGS. 5-7 are diagrams of example implementations 500/600/700 associated with dynamic polarization control for optical emitters.

As shown in FIG. 5, for the case of nₑ being aligned with the long axis of the liquid crystal, a liquid crystal component (e.g., a set of liquid crystal molecules) may be controlled by two sets of electrodes. In a first orientation 510, a top electrode and a bottom electrode are controlled to a positive bias and a negative bias, respectively. In contrast, a left electrode and a right electrode are floating (e.g., grounded or at a neutral bias). Accordingly, the set of liquid crystal molecules are aligned in a top-bottom (or north-south) orientation. In contrast, in a second orientation 520, the top electrode and the bottom electrode are floating, whereas the left electrode and the right electrode are controlled to a positive bias and a negative bias, respectively. In this case, the set of liquid crystal molecules are aligned in a left-right (or east-west) orientation.

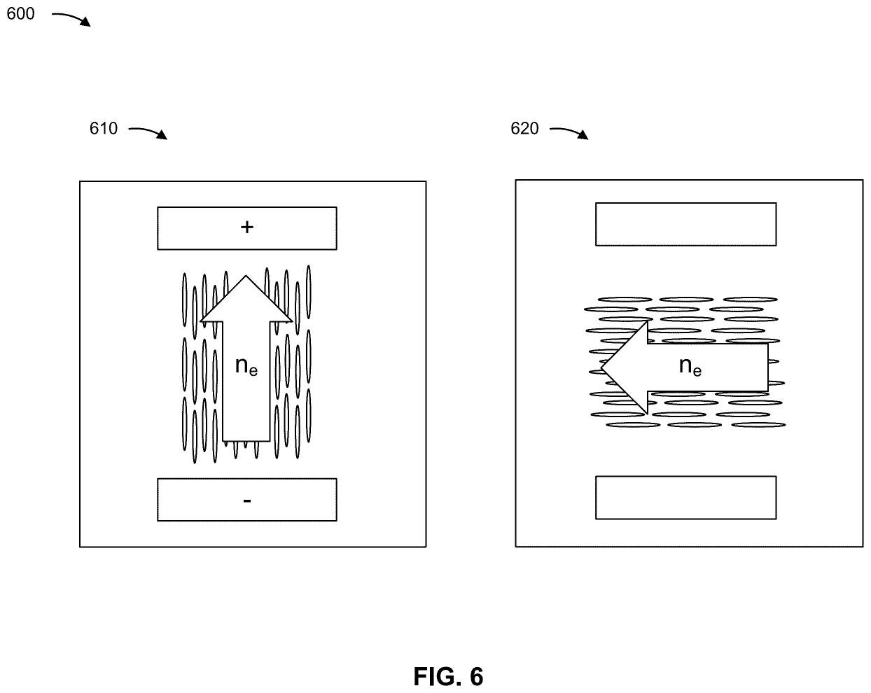

As shown in FIG. 6, for the case of nₑ being aligned with the long axis of the liquid crystal, rather than two sets electrodes, a liquid crystal component may be controlled by a single set of electrodes. In a first orientation 610, a top electrode and a bottom electrode are controlled to a positive bias and a negative bias, respectively. Accordingly, the set of liquid crystal molecules are aligned in a top-bottom (or north-south) orientation. In contrast, in a second orientation 620, when the top electrode and the bottom electrode are floating, the set of liquid crystal molecules may revert to an initial orientation, which, in this case, is a left-right (or east-west) orientation. In this way, by using a natural orientation of liquid crystal molecules (e.g., when not biased) aligned to a first polarization state, an optical emitter can have dynamic control of orthogonal (or, in another example, non-orthogonal) polarization states using only a single set of electrodes.

Although the liquid crystal molecules are described as having a natural or initial orientation, also called a rest-state orientation (e.g., when a set of electrodes are not biased to control an orientation of the liquid crystal molecules), the liquid crystal molecules may be configured to an arbitrary orientation using one or more processes for manufacturing, depositing, or containing, among other examples, the liquid crystal molecules. For example, the liquid crystal component (or a surface thereof) can be patterned or etched to cause a particular rest-state orientation.

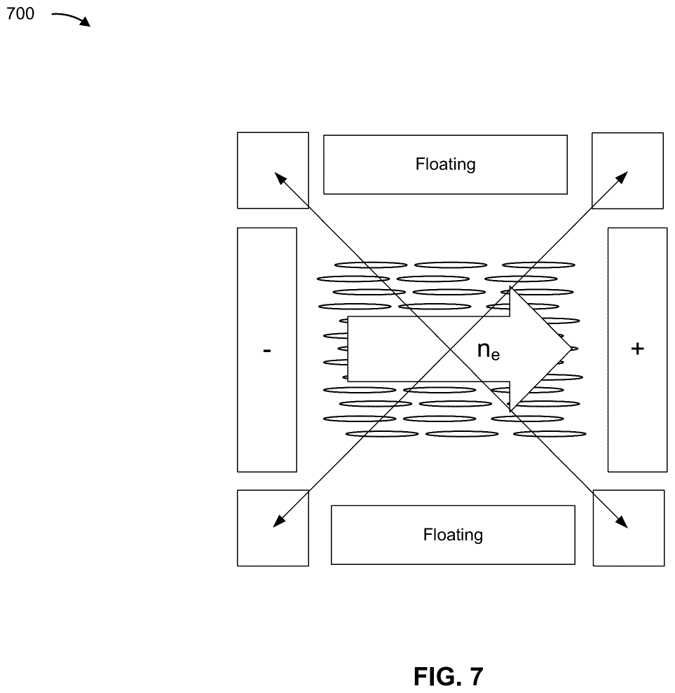

As shown in FIG. 7, for the case of nₑ being aligned with the long axis of the liquid crystal, additional sets of electrodes may be used to control the liquid crystal molecules. For example, a set of northeast-southwest and/or northwest-southeast electrodes may be provided. In this case, the east-west, north-south, northeast-southwest, and/or northwest-southeast electrodes can be controlled to obtain additional orientations (e.g., 45 degree polarizations), such as a north-south orientation, an east-west orientation, a northeast-southwest orientation, a northwest-southeast orientation, or another intermediate orientation (e.g., an orientation between east-west and northeast-southwest, among other examples). The additional orientations may, for example, correspond to additional polarization states that have different levels of x-polarized light and y-polarized light to enable differential sensing configurations (e.g., sensing of a first amount of x-polarized light and sensing of a second amount of y-polarized light). For example, other liquid crystal orientations and associated polarization states may be used to match an environment through which a beam is to propagate, thereby aligning a polarization state of the beam to a configuration that, for example, maximizes propagation (and minimizes attenuation) through the environment.

As indicated above, FIGS. 5-7 are provided as examples. Other examples may differ from what is described with regard to FIGS. 5-7. In particular, the concepts shown in FIGS. 5-7 would supply in a similar way to a liquid crystal in which the long axis of the molecule is aligned with no of the liquid crystal.

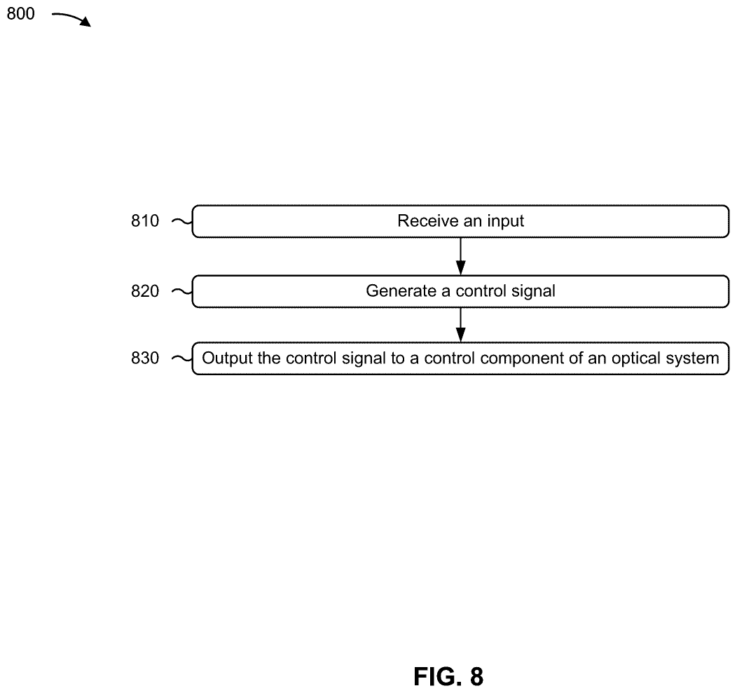

FIG. 8 is a flowchart of an example process 800 associated with dynamic polarization control for optical emitters. In some implementations, one or more process blocks of FIG. 8 are performed by a controller (e.g., control component 230 or a controller thereof). In some implementations, one or more process blocks of FIG. 8 are performed by another device or a group of devices separate from or including the controller.

As shown in FIG. 8, process 800 may include receiving an input (block 810). For example, the controller may receive an input, as described above. In some implementations, the input may include a measurement of an optical beam. For example, the controller may receive an input identifying a current polarization state of the optical beam. Additionally, or alternatively, the controller may receive an input identifying a desired polarization state of the optical beam.

As further shown in FIG. 8, process 800 may include generating a control signal (block 820). For example, the controller may generate a control signal, as described above. In some implementations, the control signal may be an electrical signal that is directed to a control component, such as an electrode, to cause the electrode to produce or receive a biasing voltage at a specified level. For example, the control signal may be an electrical signal that is directed to cause a level of voltage being provided to a set of electrodes to be changed from a first level to a second level. Additionally, or alternatively, the control signal may be an electrical, magnetic, or optical signal that is directed to one or more circuit components to control which electrode (of a set of electrodes) receives biasing voltage. For example, the control signal may be a switching signal to change biasing voltage from being directed to a first set of electrodes to being directed to a second set of electrodes.

As further shown in FIG. 8, process 800 may include outputting the control signal to a control component of an optical system (block 830). For example, the controller may output the control signal to a control component of an optical system. The control component may be configured to control an orientation of molecules within a liquid crystal component disposed on a surface of an optical emitter of the optical system. In some implementations, a polarization state of light emitted by the optical system is based on the orientation of the molecules within the liquid crystal component, as described above.

Process 800 may include additional implementations, such as any single implementation or any combination of implementations described below and/or in connection with one or more other processes described elsewhere herein.

In a first implementation, process 800 includes receiving another input, generating a new control signal, the new control signal being different from the control signal, and outputting the new control signal to the control component of the optical system, the new control signal being configured to change the orientation of the molecules within the liquid crystal component from a first orientation associated with the control signal to a second orientation associated with the new control signal, and the second orientation being orthogonal to the first orientation.

In a second implementation, alone or in combination with the first implementation, receiving the input comprises receiving a feedback signal indicating the polarization state of the light, and generating the control signal comprises generating the control signal to adjust the polarization state of the light based on the feedback signal.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations.

Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical system, comprising:
an optical emitter configured to emit a beam,
wherein the optical emitter is a vertical cavity surface emitting laser (VCSEL),
wherein the VCSEL is a top-emitting VCSEL or a bottom-emitting VCSEL;
a liquid crystal component,
the liquid crystal component being disposed on a surface of the optical emitter; and
a control component.

2. The optical system of claim 1, further comprising:
the control component configured to control the liquid crystal component to adjust a polarization state of the beam.

3. The optical system of claim 2, wherein the control component includes at least one set of electrodes.

4. The optical system of claim 2, wherein the control component is configured to cause a rotation of liquid crystal molecules of the liquid crystal component.

5. The optical system of claim 2, wherein the control component is configured to control the liquid crystal component to adjust an orientation of a refractive index of the liquid crystal component.

6. The optical system of claim 1, further comprising:
an anti-reflective coating disposed on a surface of the liquid crystal component.

7. The optical system of claim 1, wherein the liquid crystal component is configured to maintain a set of molecules of the liquid crystal component in a nematic phase.

8. The optical system of claim 1, wherein the liquid crystal component and the optical emitter are configured to generate a single, adjustable configured polarization.

9. A vertical cavity surface emitting laser (VCSEL) assembly, comprising:
a VCSEL,
wherein the VCSEL includes a substrate,
a bottom distributed Bragg reflector (DBR) disposed on the substrate,
an active region, and
a top DBR, wherein the bottom DBR and the top DBR sandwich the active region; and
an integrated liquid crystal cell disposed on the top DBR to control a polarization of light emitted from the VCSEL.

10. The VCSEL assembly of claim 9, wherein a reflection by the top DBR is based on an orientation of molecules within the integrated liquid crystal cell.

11. The VCSEL assembly of claim 9, wherein a gain threshold of the VCSEL is based on an orientation of molecules within the integrated liquid crystal cell.

12. The VCSEL assembly of claim 9, wherein the integrated liquid crystal cell is configured to induce generation of light with a first polarization in the VCSEL and suppress generation of light with a second polarization in the VCSEL.

13. The VCSEL assembly of claim 9, further comprising:
a set of control electrodes configured to control an orientation of molecules within the integrated liquid crystal cell,
wherein the set of control electrodes are oriented to a pair of orthogonal polarizations to align the orientation of molecules within the integrated liquid crystal cell to one of the pair of orthogonal polarizations based on a control signal.

14. The VCSEL assembly of claim 9, further comprising:
three or more sets of control electrodes configured to control an orientation of molecules within the integrated liquid crystal cell to three or more orientations.

15. The VCSEL assembly of claim 14, wherein a polarization of emitted light from the VCSEL assembly is controllable to the three or more orientations of the orientation of the molecules within the integrated liquid crystal cell.

16. The VCSEL assembly of claim 9, wherein a refractive index associated with the VCSEL is based on an orientation of molecules within the integrated liquid crystal cell.

17. The VCSEL assembly of claim 9, wherein a loss, associated with the liquid crystal cell, of emitted light is less than 10%.

18. A method, comprising:
receiving, by a controller, an input;
generating, by the controller, a control signal; and
outputting, by the controller, the control signal to a control component of an optical system,
the control component being configured to control an orientation of molecules within a liquid crystal component disposed on a surface of an optical emitter of the optical system,
a polarization state of light emitted by the optical system being based on the orientation of the molecules within the liquid crystal component.

19. The method of claim 18, further comprising:
receiving another input;
generating a new control signal, the new control signal being different from the control signal; and
outputting the new control signal to the control component of the optical system,
the new control signal being configured to change the orientation of the molecules within the liquid crystal component from a first orientation associated with the control signal to a second orientation associated with the new control signal, and
the second orientation being orthogonal to the first orientation.

20. The method of claim 18, wherein receiving the input comprises:
receiving a feedback signal indicating the polarization state of the light; and
wherein generating the control signal comprises:
generating the control signal to adjust the polarization state of the light based on the feedback signal.
